(19) United States
(12) Patent Application Publication
(10) Pub. No.: US 2009/0086153 A1
(43) Pub. Date: Apr. 2, 2009

(54) STRIP-SHAPED BASE METAL FOR LIQUID CELL, MULTI-FACE CHAMFERED BASE MATERIAL FOR LIQUID CELL, SUBSTRATE FOR ARRAY SUBSTRATE, AND LIQUID CELL MANUFACTURING METHOD

(75) Inventors: Kazunori Hayakawa, Ishikawa (JP); Yasuhiro Yamamoto, Ishikawa (JP); Kenichi Goshoo, Ishikawa (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Toshiba Matsushita Display Technology Co., Ltd., Tokyo (JP)

(21) Appl. No.: 12/297,550

(22) PCT Filed: Feb. 18, 2008
(86) PCT No.: PCT/JP08/52664

§ 371 Date: Oct. 17, 2008

(30) Foreign Application Priority Data
Feb. 19, 2007 (JP) 2007-038622

(51) Int. Cl. G02F 1/1333; H01L 21/00

(52) U.S. Cl. 349/158; 438/30; 257/E21.001

(57) ABSTRACT

Shield patterns which are formed in a liquid crystal cell region on a substrate for an array substrate, disposed along a border with another adjacent liquid crystal cell region, outside a predetermined control wiring pattern, and are for shielding the liquid crystal cell region, and a connecting wiring line connecting the shield patterns opposed to each other across a border to which at least a pair of liquid crystal cell regions adjacent to each other are adjacent are included.

### CROSS-REFERENCE TO RELATED APPLICATIONS

This application is a U.S. national phase application of PCT International Patent Application No. PCT/JP2008/052664 filed on Feb. 18, 2008, claiming the benefit of priority of Japanese Patent Application No. 2007-038622 filed on Feb. 19, 2007, all of which are incorporated by reference herein in their entirety.

### TECHNICAL FIELD

The present invention relates to a rectangular base material for liquid crystal cells, a base material for obtaining multiple liquid crystal cells, a substrate for an array substrate and a manufacturing method of a liquid crystal cell, to which measures against electrostatic discharge (ESD) are applied in the manufacturing process of the liquid crystal cells and the like.

### BACKGROUND ART

In recent years, active matrix type liquid crystal display devices have been widely used as display devices for personal computers, televisions, portable information equipment, portable telephones, GPS (Global Positioning System) terminals and the like, and further as projection type display devices of projectors and the like by taking the advantage of the characteristics of slimness, light weight and low power consumption.

The active matrix type liquid crystal cells which are used in such liquid crystal display devices have the problem of electrostatic discharge (ESD: Electro Static Discharge) which occurs in the manufacturing stage as in the case of semiconductor devices such as LSI and IC.

For example, in the liquid crystal cell process which is the process of fabricating liquid crystal cells, a base material 101 for obtaining multiple liquid crystal cells (see FIG. 10) or a rectangular base material 103 for liquid crystal cells (see FIG. 11) are electrically charged by frictional static electricity occurred with a matter such as a tool. Further, the potential of the base material 101 for obtaining multiple liquid crystal cells or the rectangular base material 103 for liquid crystal cells is raised, since an insulator, a jig or the like in the vicinity of the base material 101 for obtaining multiple liquid crystal cells or the rectangular base material 103 for liquid crystal cells is electrostatically charged.

When the base material 101 for obtaining multiple liquid crystal cells and the rectangular base material 103 for liquid crystal cells are electrically charged like this, static electricity is discharged from the base material 101 for obtaining multiple liquid crystal cells or the rectangular base material 103 for liquid crystal cells to other conductors, ESD surge, that is, an abnormal voltage which instantly occurs due to the electrostatic discharge flows into liquid crystal cell regions 102 (see FIGS. 10 and 11) to be made liquid crystal cells and highly likely to damage the liquid crystal cells.

Alternatively, when static electricity stored in a human body which handles the base material 101 for obtaining multiple liquid crystal cells or the rectangular base material 103 for liquid crystal cells is discharged as the ESD surge to the base material 101 for obtaining multiple liquid crystal cells or the rectangular base material 103 for liquid crystal cells, and when there is no other escape route than the base material 101 for obtaining multiple liquid crystal cells or the rectangular base material 103 for liquid crystal cells, the liquid crystal cell regions 102 to be made the liquid crystal cells which are formed in the base material 101 for obtaining multiple liquid crystal cells or the rectangular base material 103 for liquid crystal cells are highly likely to be damaged.

Thus, the conventional liquid crystal cell process for manufacturing liquid crystal cells will be described hereinafter, and the conventional measures against reduction in yield due to the electrostatic discharge in the liquid crystal process will be described.

In the conventional liquid crystal cell process which will be described hereinafter, the rectangular base materials 103 for liquid crystal cells in which the liquid crystal cell regions 102 are arranged adjacently to one another in a line are obtained by cutting the base material 101 for obtaining multiple liquid crystal cells in which liquid crystal cell regions to be made liquid crystal cells are formed adjacently to one another in a matrix form, and a liquid crystal material is injected in the state of the rectangular base material 103 for liquid crystal cells, after which, the rectangular base material 103 for liquid crystal cells is cut into each of individual liquid crystal cells (see, for example, Japanese Patent Laid-Open No. 2005-140884).

The liquid crystal cell (display panel body) of an active matrix type liquid crystal display device has the configuration in which the periphery of the liquid crystal material which is held between a pair of insulating substrates via alignment layers on the substrate surfaces is sealed with a sealing material. At least one of the pair of insulating substrates is transparent, and configures the liquid crystal display surface. In an active matrix type liquid crystal display device, one of the pair of insulating substrates is called an array substrate, and the other one is called an opposite substrate.

The array substrate has the configuration in which a plurality of signal lines and a plurality of scanning lines are disposed in a matrix form on the glass substrate to be made the base material, and in the vicinity of the intersection of each of the signal lines and each of the scanning lines, a pixel electrode constituted of ITO (Indium Tin Oxide) and each of the signal lines are connected via a thin film transistor (hereinafter, called TFT) which functions as a switch element.

Meanwhile, the configuration of the opposite substrate is as follows. A light shield film in a matrix form for shielding light from the TFTs and the periphery of pixel electrodes is disposed on the glass substrate to be made the base material, and the opposite electrodes constituted of ITO are disposed. In order to perform color display, color filter layers for assigning the colors of red (R), green (G) and blue (B) to each of the pixels are stacked.

First, each step of producing the glass substrate for an array substrate will be described.

First, the glass substrate for an array substrate on which the above descried signal lines, scanning lines and the like are formed is input in the manufacturing line, a resin material such as polyimide to be made the alignment layer is coated on the insides of a plurality of liquid crystal cell regions on the glass substrate for an array substrate by an offset printing method, and the coated resin material is heat-treated and thermoset. Thereafter, the surface of the thermoset resin material is drawn and aligned in a fixed direction.

Thereafter, the sealing compound is coated on the periphery of the display screens in the plurality of liquid crystal cell regions on the glass substrate for an array substrate.

Next, each step of producing the glass substrate for an opposite substrate will be described.

The glass substrate for an opposite substrate on which the above described color filter layer and the like are formed is input in the manufacturing line, a resin material such as polyimide to be made an alignment layer is coated on the insides of a plurality of liquid crystal cell regions on the glass substrate for an opposite substrate by an offset printing method, and the coated resin material is heat-treated and thermoset. Thereafter, the surface of the thermoset resin material is drawn and aligned in a fixed direction.

Thereafter, bead-shaped spacers which play a role of keeping the gap between the glass substrate for an opposite substrate and the glass substrate for an array substrate constant are sprayed to the glass substrate for an opposite substrate.

Next, the process of ultimately manufacturing individual liquid crystal cells through the process of producing the base material 101 for obtaining multiple liquid crystal cells and the rectangular base material 103 for liquid crystal cells by bonding the glass substrate for an array substrate and the glass substrate for an opposite substrate will be described.

The glass substrate for an array substrate which finishes alignment treatment and sealing compound coating, and the glass substrate for an opposite substrate which finishes alignment treatment and spacer spraying are superimposed on each other and bonded to each other while the liquid crystal cell regions of both the substrates are accurately positioned with the alignment-treated surfaces opposed to each other.

Thereafter, the sealing compound is cured, and the base material for obtaining multiple liquid crystal cells is obtained.

FIG. 10 shows one example of the base material for obtaining multiple liquid crystal cells as the base material 101 for obtaining multiple liquid crystal cells. A plurality of liquid crystal cell regions 102 to be made individual liquid crystal cells after manufacturing, are disposed adjacently to one another in a line in each row direction, and also disposed adjacently to each other in a line in each column direction. Specifically, in the base material 101 for obtaining multiple liquid crystal cells, the liquid crystal cell regions 102 are disposed adjacently to one another in a matrix form.

Like this, in the base material 101 for obtaining multiple liquid crystal cells, the liquid crystal cell regions 102 are arranged adjacently to one another in the matrix form, whereby the glass substrate for an array substrate and the glass substrate for an opposite substrate can be used without wasting anything, and the number of steps in a cutting process which will be described later can be reduced.

Thereafter, the glass substrate for an array substrate and the glass substrate for an opposite substrate which are bonded to each other are cut along the borders of the liquid crystal cell regions 102. Thus, a plurality of rectangular base materials for liquid crystal cells shown in FIG. 11 can be obtained.

FIG. 11 is an enlarged view of the rectangular base material 103 for liquid crystal cells corresponding to part A shown in FIG. 10. In FIG. 11, a plurality of liquid crystal cell regions 102 are arranged adjacently to one another in a line in the row direction.

In the rectangular base material 103 for liquid crystal cells shown in FIG. 11, a shield pattern 4a and a shield pattern 4b are formed along a border B between each of the liquid crystal cell regions 102 and another adjacent liquid crystal cell region 102. Out of the shield patterns 4a and 4b, only the shield pattern 4a is electrically connected to an opposite electrode not illustrated which is formed in the liquid crystal cell region 102 of the glass substrate for an opposite substrate, via a conductive paste 5. Connection of the shield pattern 4a and the opposite electrode formed in the liquid crystal cell region 102 of the glass substrate for an opposite substrate is performed after the step of bonding the glass substrate for an array substrate and the glass substrate for an opposite substrate.

Next, a liquid crystal material is injected to a clearance formed by the glass substrate for an opposite substrate and the glass substrate for an array substrate in a plurality of liquid crystal cell regions 102 from liquid crystal injection holes 6 of the rectangular base material 103 for liquid crystal cells shown in FIG. 11.

Thereafter, the liquid crystal injection holes 6 of the rectangular base material 103 for liquid crystal cells are sealed by using a sealing compound 7.

Subsequently, polarizing plates are bonded to both sides of each of the liquid crystal cell regions 102 of the rectangular base material 103 for liquid crystal cells.

Finally, the rectangular base material 103 for liquid crystal cells is cut at the border B of each of the liquid crystal cell regions 102.

The liquid crystal cells are fabricated as above.

In the base material 101 for obtaining multiple liquid crystal cells shown in FIG. 10, and the rectangular base material 103 for liquid crystal cells shown in FIG. 11, the shield pattern 4a and the shield pattern 4b are formed along the border B between each of the liquid crystal cell regions 102 and another liquid crystal cell region 102. Even when electrostatic discharge occurs and ESD surge flows into the liquid crystal cell regions 102, in each of the above described process steps, further inflow of the ESD surge to the inside of the liquid crystal cell regions 102 can be restrained by the shield patterns 4a and the shield patterns 4b. Specifically, ESD surge can be restrained from flowing into the scanning lines and TFTs formed in the liquid crystal cell regions 102 and damaging the TFTs and the like formed inside the liquid crystal cell regions 102.

### DISCLOSURE OF THE INVENTION

### Problems to be Solved by the Invention

In recent years, the display regions of liquid crystal cells configuring liquid crystal display devices have larger screens, while there is a strong demand for designing the liquid crystal cells to suppress an increase in the size of the liquid crystal cells themselves as much as possible. Therefore, the spaces between the wiring lines such as the control wiring lines and the like of the liquid crystal cells have been made very small.

Therefore, in the above described conventional base material 101 for obtaining multiple liquid crystal cells, out of a pair of shield patterns 4a and 4b provided at each of the liquid crystal cell regions 102 shown in FIG. 10, only the shield pattern 4b is electrically connected to the opposite electrode formed in the liquid crystal cell region 102 via the conductive paste 5, and insertion of the conductive paste 5 is omitted in the other shield pattern 4a for securing the display region. Specifically, the other shield pattern 4a is not connected to the opposite electrode formed in the liquid crystal cell region 102.

In the above configuration, the following problem occurs. Specifically, the capacitance of the shield pattern 4a and the capacitance of the shield pattern 4b are unbalanced. Therefore, ESD easily occurs between the shield pattern 4a and the shield pattern 4b which are close to each other and disposed in the border B between the adjacent liquid crystal cell regions 102.

Further, in order to satisfy the above described demand, it is sometimes impossible that the shapes such as the widths or the like of the shield pattern 4a and the shield pattern 4b which are adjacent to each other across the border to which an adjacent pair of liquid crystal cell regions 102 and 102 are adjacent are designed to be the same shapes. In such a case, the capacitance of the shield pattern 4a and the capacitance of the shield pattern 4b are unbalanced. Therefore, ESD easily occurs between the shield patterns 4a and 4b which are close to each other.

Further, in order to satisfy the above described demand in the design of the size of the liquid crystal cell made in view of the display region of the liquid crystal cell, the shield pattern 4a and the shield pattern 4b which are adjacent to each other across the border B to which an adjacent pair of liquid crystal cell regions 102 are adjacent as shown in FIG. 11 have to be designed to be close to each other. Therefore, ESD easily occurs between the shield pattern 4a and the shield pattern 4b which are close to each other.

In any of the above described cases, when ESD surge flows into the base material 101 for obtaining multiple liquid crystal cells shown in FIG. 10 or the rectangular base material 103 for liquid crystal cells shown in FIG. 11, ESD occurs between a pair of shield patterns 4a and 4b which are adjacent to each other across the border B to which a pair of liquid crystal cell regions 102 adjacent to each other are adjacent, and there arises the problem that the ESD surge flows into the control wiring line inside the liquid crystal cell region 102 with larger capacitance from the shield pattern, and flows into the scanning lines to damage the TFTs and the like.

Alternatively, ESD occurs between the shield patterns 4a and 4b which are close to each other, and there arises the problem that the ESD surge flows into the control wiring line inside the liquid crystal cell region 102 with larger capacitance from the shield pattern 4a or 4b, and the ESD surge flows into the scanning lines to damage the TFTs and the like.

Actually, in the entire above described liquid crystal cell process, a very small number of damaged products due to ESD occur even though the shield patterns 4a and 4b are formed on the glass substrate for an array substrate.

As described above, in the conventional liquid crystal cell process for manufacturing liquid crystal cells by forming the rectangular base material for liquid crystal cells in which the liquid crystal cell regions are arranged adjacently in a line, there is the problem of occurrence of reduction in yield by electrostatic discharge, though the measures against the electrostatic discharge is taken.

In view of the above described problems, the present invention has an object to provide a base material for obtaining multiple liquid crystal cells, a rectangular base material for liquid crystal cells, a substrate for an array substrate, and a manufacturing method of a liquid crystal cell, which are capable of suppressing reduction in yield due to electrostatic discharge.

### Means for Solving the Problems

The 1^{st} aspect of the present invention is a rectangular base material for liquid crystal cells having a substrate for an array substrate and a substrate for an opposite substrate bonded to said substrate for an array substrate, and having a plurality of liquid crystal cell regions arranged adjacently to one another in a line on said substrate for an array substrate and said substrate for an opposite substrate, comprising:

a pixel electrode pattern formed in a matrix form in said liquid crystal cell regions on said substrate for an array substrate;

a predetermined control wiring pattern formed on said liquid crystal cell region on said substrate for an array substrate and for being connected to said pixel electrode pattern;

a shield pattern which is formed in said liquid crystal cell region on said substrate for an array substrate, is disposed outside said predetermined control wiring pattern along a border with another adjacent liquid crystal cell region, and is for shielding said liquid crystal cell region; and

a connecting wiring line electrically connecting said shield patterns adjacent across the border to which at least a pair of said liquid crystal cell regions adjacent to each other are adjacent.

The 2^{nd} aspect of the present invention is the rectangular base material for liquid crystal cells according to the 1^{st} aspect of the present invention

wherein an opposite electrode is formed in each of said liquid crystal cell regions on said substrate for an opposite substrate, and

only one of said adjacent shield patterns is connected to said opposite electrode via a conductive member.

The 3^{rd} aspect of the present invention is the rectangular base material for liquid crystal cells according to the 1^{st} aspect of the present invention,

wherein a line width of one of said adjacent shield patterns is smaller than a line width of the other one at portions to which said connecting wiring line is connected.

The 4^{th} aspect of the present invention is the rectangular base material for liquid crystal cells according to the 1^{st} aspect of the present invention,

wherein widths of said adjacent shield patterns differ from each other at portions to which said connecting wiring line is connected, and

resistance of said portion of said shield pattern of a small width and resistance of said portion of said shield pattern of a large width are equal.

The 5^{th} aspect of the present invention is the rectangular base material for liquid crystal cells according to the 4^{th} aspect of the present invention,

wherein a thickness of said portion of said shield pattern of the small width is larger than a thickness of said portion of said shield pattern of the large width.

The 6^{th} aspect of the present invention is the rectangular base material for liquid crystal cells according to the 4^{th} aspect of the present invention,

wherein electrical conductivity of said portion of said shield pattern of the small width is higher than electrical conductivity of said portion of said shield pattern of the large width.

The 7^{th} aspect of the present invention is the base material for obtaining multiple liquid crystal cells from which a plurality of the rectangular base materials for liquid crystal cells according to the 1^{st} aspect of the present invention can be obtained by cutting.

The 8^{th} aspect of the present invention is a substrate for an array substrate having a plurality of liquid crystal cell regions arranged adjacently to one another in a line, comprising:

a pixel electrode pattern formed in a matrix form in said liquid crystal cell region;

a predetermined control wiring pattern formed in said liquid crystal cell region and for being connected to said pixel electrode pattern;

a shield pattern which is formed in said liquid crystal cell region, is disposed outside said predetermined control wiring pattern along a border with another adjacent liquid crystal cell region, and is for shielding said liquid crystal cell region; and

a connecting wiring line electrically connecting said shield patterns adjacent across a border to which at least a pair of said liquid crystal cell regions adjacent to each other are adjacent.

The 9^{th} aspect of the present invention is a manufacturing method of a liquid crystal cell, comprising:

a pixel electrode pattern forming step for forming a pixel electrode pattern disposed in a matrix form in a plurality of liquid crystal cell regions arranged adjacently to one another in a line on a substrate for an array substrate;

a control wiring pattern forming step of forming a predetermined control wiring pattern for being connected to said pixel electrode pattern in said liquid crystal cell regions on said substrate for an array substrate;

a shield pattern forming step of forming a shield pattern, which is disposed outside said predetermined control wiring pattern along a border of said liquid crystal cell region on said substrate for an array substrate with another adjacent liquid crystal cell region and is for shielding said liquid crystal cell region;

a connecting wiring line forming step of electrically connecting said shield patterns adjacent across the border to which at least a pair of said liquid crystal cell regions adjacent to each other are adjacent;

a bonding step of bonding a substrate for an opposite substrate having a plurality of liquid crystal cell regions adjacent to one another in a line and said substrate for an array substrate to each other by a sealing compound so that said plurality of liquid crystal cell regions correspond to one another to obtain a base material for obtaining multiple liquid crystal cells;

a first cutting step of cutting said base material for obtaining multiple liquid crystal cells in a horizontal direction to obtain a rectangular base material for liquid crystal cells;

an injecting step of injecting a liquid crystal material in clearances formed by said substrate for an array substrate and said substrate for an opposite substrate in said plurality of liquid crystal cell regions of said rectangular base material for liquid crystal cells; and

a second cutting step of cutting said rectangular base material for liquid crystal cells at the borders of said liquid crystal cell regions.

### EFFECT OF THE INVENTION

The present invention can provide a rectangular base material for liquid crystal cells, a base material for obtaining multiple liquid crystal cells, a substrate for an array substrate and a manufacturing method of a liquid crystal cell, which are capable of suppressing reduction in yield due to electrostatic discharge.

### BRIEF DESCRIPTION OF THE DRAWINGS

FIG. 1 is a plane view showing one example of a base material for obtaining multiple liquid crystal cells in an embodiment of the present invention.

FIG. 2 is a plane view showing one example of a rectangular base material for liquid crystal cells in the embodiment of the present invention.

FIG. 3 is a partial enlarged plane view of the rectangular base material for liquid crystal cells in the embodiment of the present invention.

FIG. 4 is a partial enlarged plane view of the rectangular base material for liquid crystal cells in the embodiment of the present invention.

FIG. 5 is a flowchart showing an outline of a TFT array process in the embodiment of the present invention.

FIG. 6(a) is a flowchart showing an outline of a process of a glass substrate for an array substrate out of a liquid crystal cell process in the embodiment of the present invention, FIG. 6(b) is a flowchart showing an outline of a process of a glass substrate for an opposite substrate out of the liquid crystal cell process in the embodiment of the present invention, and FIG. 6(c) is a flowchart showing an outline of a process of manufacturing a liquid crystal cell through the base material for obtaining multiple liquid crystal cells and the rectangular base material for liquid crystal cells of the liquid crystal cell process in the embodiment of the present invention.

FIG. 7 is a view showing another configuration example of the rectangular base material for liquid crystal cells in the embodiment of the present invention.

FIG. 8(a) is a view showing another configuration example of the rectangular base material for liquid crystal cells in the embodiment of the present invention, and FIG. 8(b) is a schematic sectional view of FIG. 8(a).

FIG. 9 is a view showing another configuration example of the rectangular base material for liquid crystal cells in the embodiment of the present invention.

FIG. 10 is a view showing one example of the conventional base material for obtaining multiple liquid crystal cells.

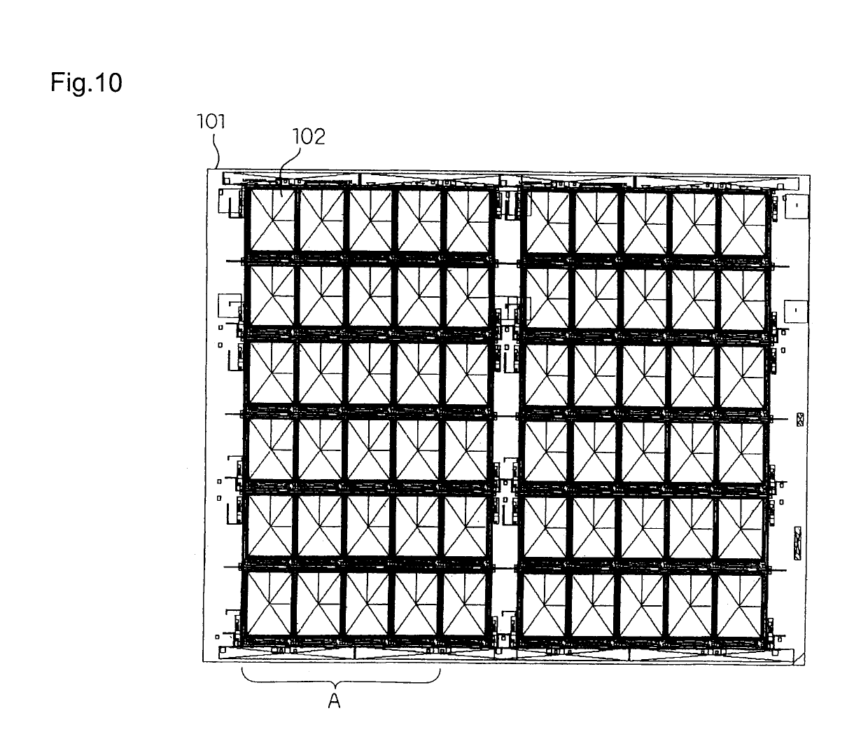

FIG. 11 is a view showing one example of the conventional rectangular base material for liquid crystal cells.

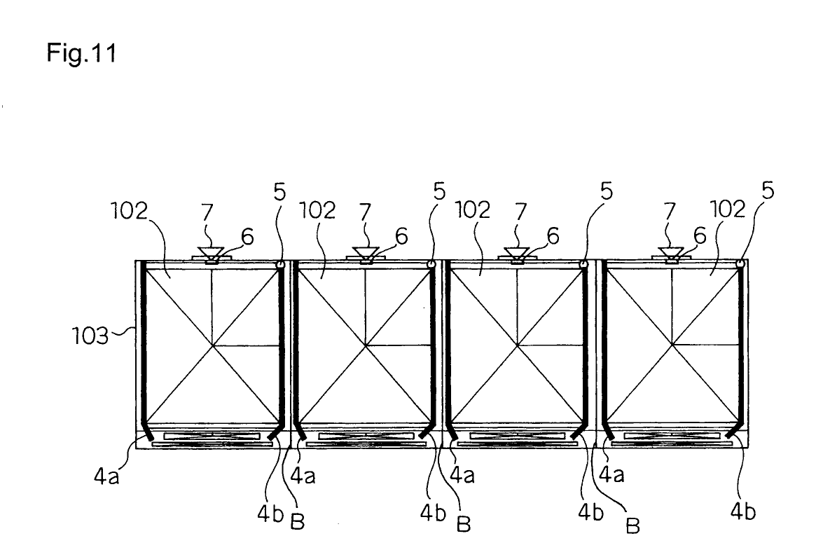

### DESCRIPTION OF SYMBOLS

1 base material for obtaining multiple liquid crystal cells
2 liquid crystal cell region
3 rectangular base material for liquid crystal cells
4a shield pattern
4b shield pattern
5 conductive paste
6 liquid crystal injection hole
7 sealing compound
8 connecting wiring line

### BEST MODE FOR CARRYING OUT THE INVENTION

Hereinafter, an embodiment of the present invention will be described with reference to the drawings.

In the present embodiment, a rectangular base material for liquid crystal cells and a base material for obtaining multiple liquid crystal cells which are one embodiment of the present invention will be described, and one embodiment of the method for manufacturing a liquid crystal cell of the present invention will be also described.

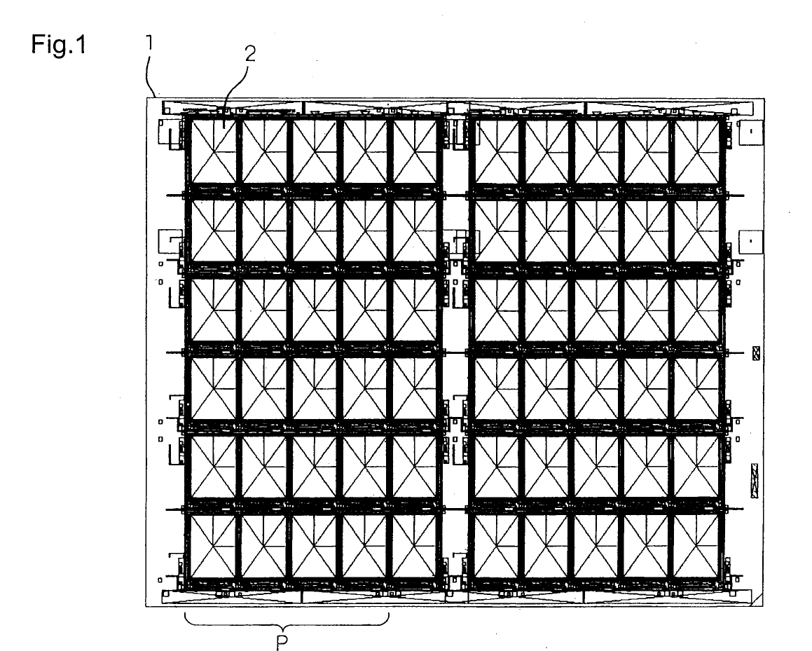

FIG. 1 is a plane view of a base material 1 for obtaining multiple liquid crystal cells of the present embodiment. As shown in FIG. 1, in the base material 1 for obtaining multiple liquid crystal cells, a plurality of liquid crystal cell regions 2 are disposed adjacently to one another in a matrix form, and a glass substrate for an array substrate and a glass substrate for an opposite substrate are bonded to each other by being accurately positioned so that the respective liquid crystal cell regions 2 are opposed to one another.

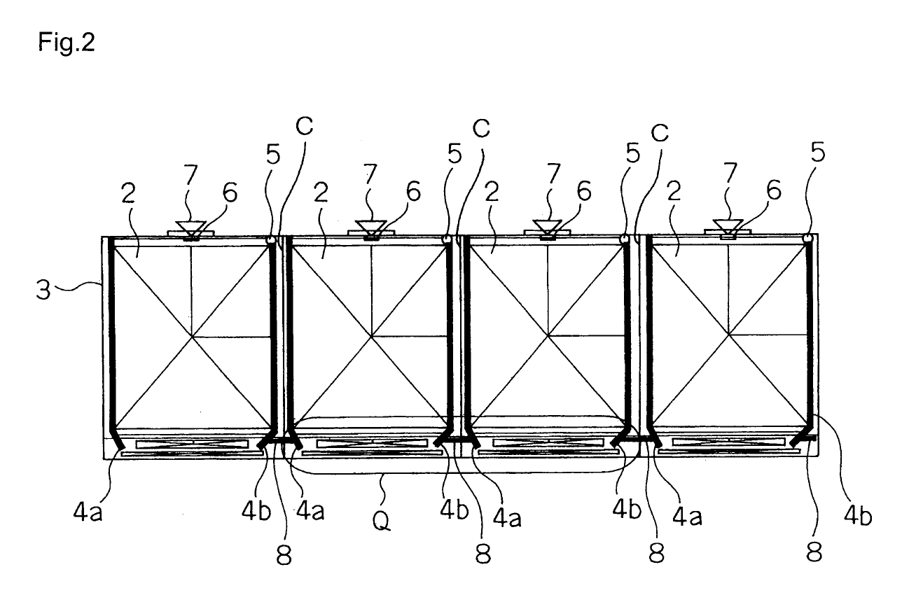

FIG. 2 is a plane view showing a configuration of the rectangular base material 3 for liquid crystal cells which is obtained by cutting the base material 1 for obtaining multiple liquid crystal cells as shown in FIG. 1, at cutting lines in the horizontal direction (borders in the horizontal direction to which the liquid crystal cell regions 2 are adjacent). In FIG. 2, the rectangular base material 3 for liquid crystal cells corresponding to part P of the base material 1 for obtaining multiple liquid crystal cells in FIG. 1 is shown as an example, but actually, when the base material 1 for obtaining multiple liquid crystal cells in FIG. 1 is cut, ten of the liquid crystal cell regions 2 are disposed in the rectangular base material 3 for liquid crystal cells. However, the present invention is not limited by the unit of cutting.

As shown in FIG. 2, a plurality of liquid crystal cell regions 2 to be made liquid crystal cells are disposed adjacently to one another in a line. A shield pattern 4a and a shield pattern 4b which are adjacent across a border C to which a pair of liquid crystal cell regions 2 adjacent to each other are adjacent are connected by a connecting wiring line 8.

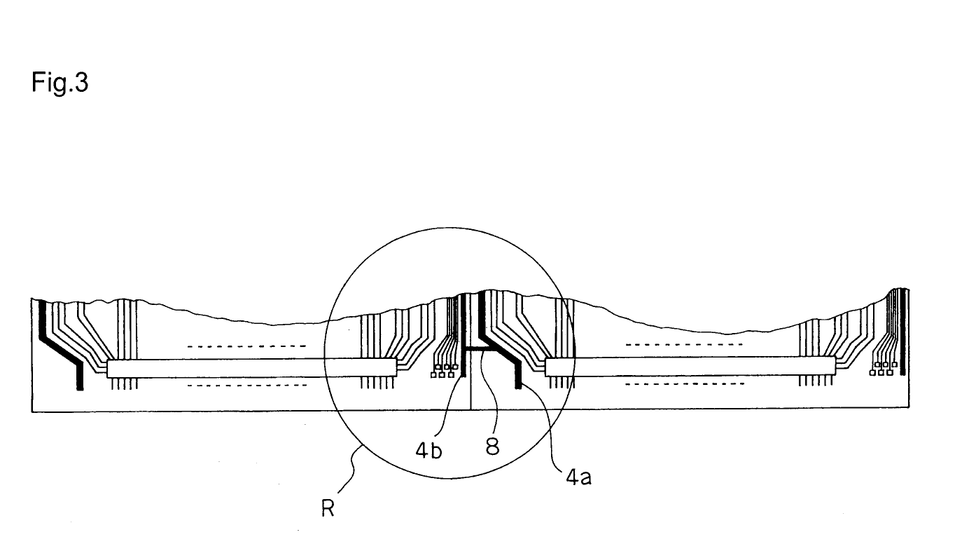

FIG. 3 is an enlarged view of essential part Q of FIG. 2. It is found that the shield pattern 4b and the shield pattern 4a are connected by the connecting wiring line 8.

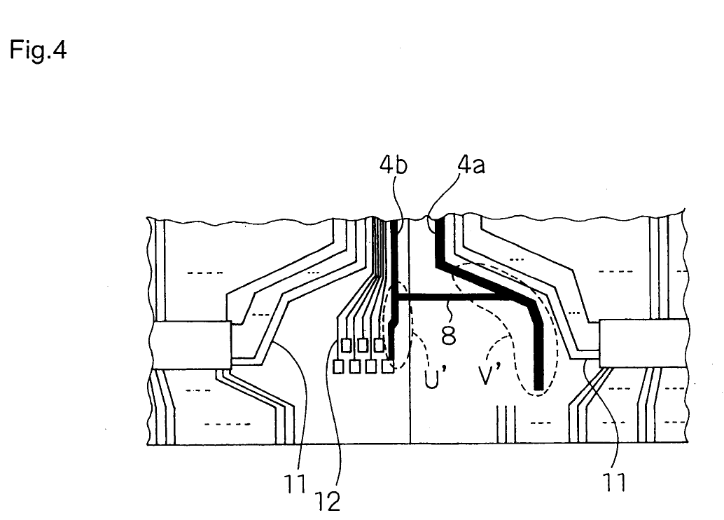

FIG. 4 is an enlarged view of essential part R of FIG. 3. It is more clearly found that the shield pattern 4b and the shield pattern 4a are connected by the connecting wiring line 8.

The rectangular base material 3 for liquid crystal cells shown in FIG. 2 has the configuration in which the glass substrate for an opposite substrate and the glass substrate for an array substrate are bonded to each other.

In the liquid crystal cell region 2 on the glass substrate for an array substrate, a pixel electrode pattern formed in a matrix form, TFT which is a switching element and the like are formed though not illustrated.

Further, in the liquid crystal cell region 2 on the glass substrate for an array substrate, predetermined control wiring lines for connecting to the pixel electrode pattern are formed. Specifically, in the liquid crystal cell region 2 on the glass substrate for an array substrate, control wiring lines such as control wiring lines 11 for connecting to scanning lines, collective inspection lines 12 for performing inspection of the liquid crystal cell shown in FIG. 4 are formed.

Further, as shown in FIG. 2, in the liquid crystal cell region 2, a liquid crystal injection hole 6 and the like are formed in addition to the shield patterns 4a and 4b. Only the shield pattern 4b out of the shield patterns 4a and 4b is connected to an opposite electrode formed in the liquid crystal cell region 2 of the glass substrate for an opposite substrate via a conductive paste, that is, a common transfer material.

A conductive paste 5 of the present embodiment is only an example of the conductive member of the present invention. The shield patterns 4a and 4b of the present embodiment are only examples of the shield patterns of the present invention.

The liquid crystal cell region 2 of the base material 1 for obtaining multiple liquid crystal cells shown in FIG. 1 also has the same configuration as the liquid crystal cell region 2 of the rectangular base material 3 for liquid crystal cells shown in FIG. 2.

As described above, the shield patterns 4a and 4b which are adjacent across the border C to which a pair of adjacent liquid crystal cell regions 2 are adjacent are connected by the connecting wiring line 8. Thereby, ESD which occurs between the shield patterns 4a and 4b which are adjacent across the border to which a pair of adjacent liquid crystal cell regions 2 are adjacent can be prevented.

Specifically, when either the shield pattern 4a or the shield pattern 4b is charged by static electricity, electric charge quickly moves to the shield pattern 4b or 4a which is not charged by passing through the connecting wiring line 8, and therefore, the shield pattern 4a and the shield pattern 4b can be always kept at the same potential.

By providing the connecting wiring line 8 like this, ESD hardly occurs between the shield patterns 4a and 4b which are adjacent across the border C to which a pair of adjacent liquid crystal cell regions 2 are adjacent.

Further, when ESD surge flows into any one of the shield patterns 4a and 4b, the shield patterns 4a and 4b of the liquid crystal cell regions 2 are connected by the connecting wiring line 8, and therefore, ESD surge can be restrained from flowing inside the liquid crystal cell regions 2.

Specifically, by connecting the shield patterns 4a and 4b which are adjacent across the border C, to which a pair of adjacent liquid crystal cell regions 2 are adjacent, by the connecting wiring line 8, the shield patterns 4a and 4b and the connecting wiring line 8 function as one capacitance as a whole. Accordingly, the capacitance becomes larger as compared with the case of the single body of the shield pattern 4a or the shield pattern 4b. Accordingly, even when ESD surge flows into the inside of the liquid crystal cell region 2, the absolute value of the voltage becomes small as compared with the case of the single body of the shield pattern 4a or the shield pattern 4b. Accordingly, ESD hardly occurs between the shield pattern 4a and the shield pattern 4b, and the control wiring lines inside of them. Thereby, ESD surge can be restrained from flowing inside the liquid crystal cell regions 2.

As above, according to the present embodiment, by adopting the configuration in which the shield patterns 4a and 4b, which are adjacent at the border to which a pair of adjacent liquid crystal cell regions 2 are adjacent, are connected by the connecting wiring line 8, the base material 1 for obtaining multiple liquid crystal cells and the rectangular base material 3 for liquid crystal cells hardly receive the influence of the electrostatic discharge, and therefore, reduction in yield of the liquid crystal cells due to electrostatic discharge can be suppressed especially at the time of manufacturing liquid crystal cells.

Next, the operation of the base material 1 for obtaining multiple liquid crystal cells and the rectangular base material 3 for liquid crystal cells of the present embodiment will be described, and a manufacturing method thereof and one embodiment of the manufacturing method of a liquid crystal cell of the present invention will be also described.

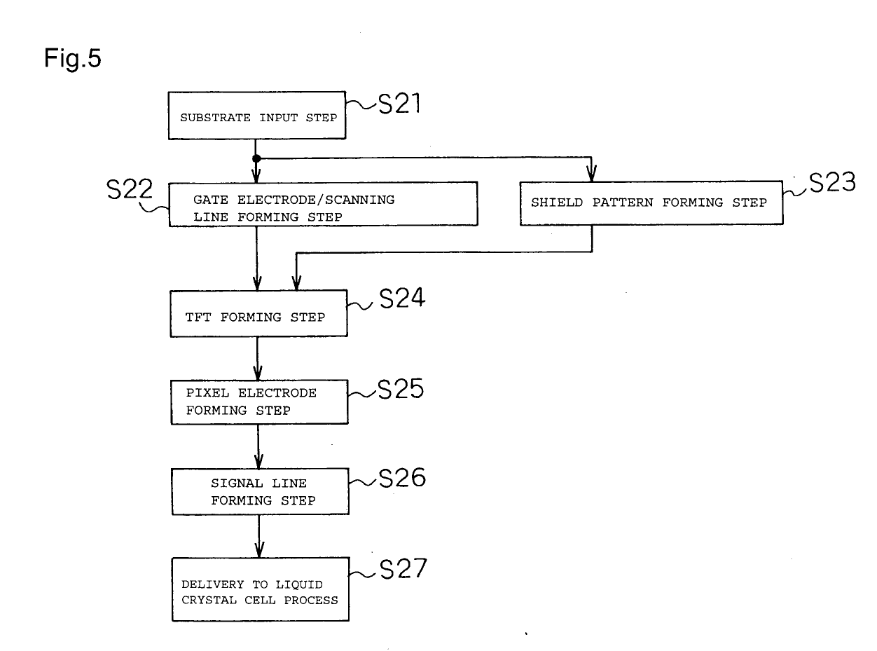

FIG. 5 shows the outline of a TFT array process for forming pixel electrode patterns, TFTs, scanning lines, signal lines and the shield patterns 4a and 4b on one surface of a glass substrate for an array substrate.

In FIG. 5, the glass substrate for an array substrate is input in a manufacturing line first (substrate input step S21).

Next, by repeating film formation and patterning, the gate electrodes and scanning lines are formed (gate electrode and scanning line forming step S22), and the shield patterns 4a and 4b are formed. At the formation of the shield patterns 4a and 4b, the connecting wiring lines 8 are also formed at the same time.

Thereafter, by repeating film formation and patterning, TFTs which are switching elements are formed (TFT forming step S24).

Next, the pixel electrodes are formed (pixel electrode forming step S26).

The completed array substrate is delivered to a liquid crystal cell process (delivery to the liquid crystal cell step S27).

Thus, the glass substrate for an array substrate is obtained. The connecting wiring lines 8 are already formed in the completed glass substrate for an array substrate, and therefore, the resistance to electrostatic discharge is improved as compared with the conventional products.

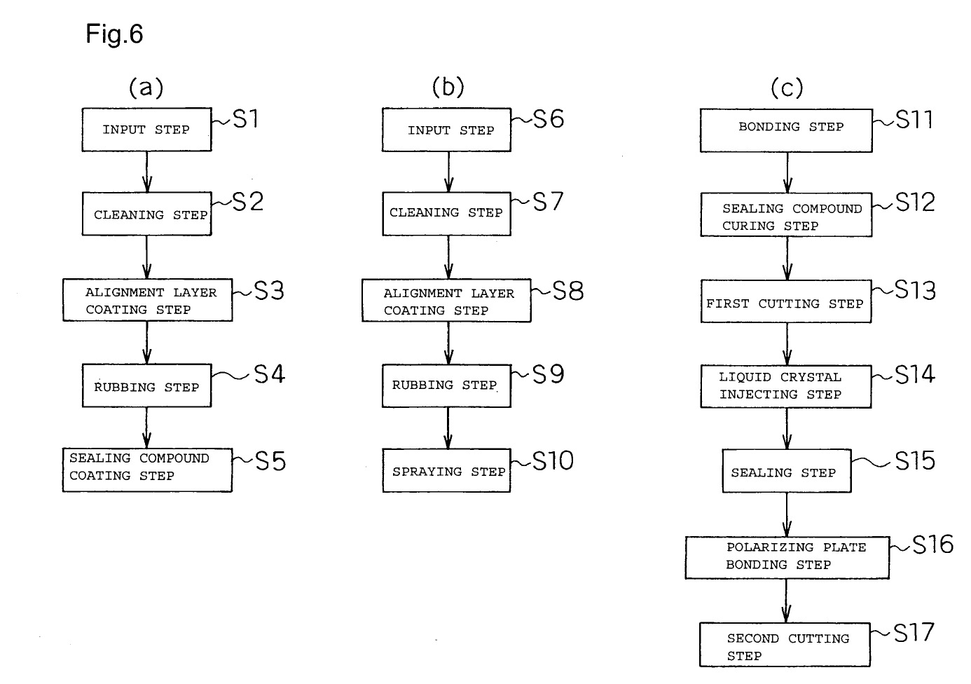

Next, FIGS. 6(a), 6(b) and 6(c) show the outline of the liquid crystal cell process for industrially fabricating the liquid crystal cells of the present embodiment.

First, each process step of the glass substrate for an array substrate will be described. FIG. 6(a) shows each process of the glass substrate for an array substrate.

First, as to the glass substrate for an array substrate, the glass substrate for an array substrate in which the pixel electrodes, TFTs, the signal lines and scanning lines, the shield patterns 4a and 4b, the connecting wiring lines 8 and the like are formed on a plurality of liquid crystal cell regions 2 arranged adjacently to one another in a matrix form is input in a manufacturing line (input step S1).

Subsequently, the input glass substrate for an array substrate is cleaned (S2).

Next, a resin material such as polyimide to be made an alignment layer is coated on the insides of a plurality of liquid crystal cell regions 2 on the glass substrate for an array substrate by an offset printing method, and the coated resin material is heat-treated and thermoset (alignment layer coating step S3).

Thereafter, by rubbing the surface of the thermoset resin material with flocked cloth or the like wound on a roller, the thermoset resin material is drawn and aligned in a fixed direction (rubbing step S4).

Thereafter, a sealing compound is coated on the periphery of the display screens in a plurality of liquid crystal cell regions 2 on the glass substrate for an array substrate with a dispenser (seal coating step S5). At this time, a gap for forming an injection hole for injecting a liquid crystal material is provided in the seal compound coated in the seal coating step S5.

Next, each of steps of the glass substrate for an opposite substrate will be described. FIG. 6(b) shows each of the steps of the glass substrate for an opposite substrate.

As to the glass substrate for an opposite substrate, the glass substrate for an opposite substrate in which a color filter layer and the like are formed on a plurality of liquid crystal cell regions 2 arranged adjacently to one another in a matrix form is input in a manufacturing line (input step S6).

Subsequently, the input glass substrate for an opposite substrate is cleaned (cleaning step S7).

Next, a resin material such as polyimide to be made an alignment layer is coated on the insides of a plurality of liquid crystal cell regions 2 on the glass substrate for an opposite substrate by an offset printing method, and the coated resin material is heat-treated and thermoset (alignment layer coating step S8).

Thereafter, by rubbing the surface of the thermoset resin material with flocked cloth or the like wound on a roller, the thermoset resin material is drawn and aligned in a fixed direction (rubbing step S9).

Thereafter, bead-shaped spacers which play a role of keeping a certain gap between the glass substrate for an opposite substrate and the glass substrate for an array substrate are sprayed to the glass substrate for an opposite substrate (spraying step S10).

Next, the process of manufacturing individual liquid crystal cells after the process of obtaining the base material 1 for obtaining multiple liquid crystal cells and the rectangular base material 3 for liquid crystal cells by bonding the glass substrate for an array substrate and the glass substrate for an opposite substrate to each other will be described.

FIG. 6(c) shows each of such steps.

Specifically, the glass substrate for an array substrate which finishes alignment treatment and seal compound coating and the glass substrate for an opposite substrate which finishes alignment treatment and spacer spraying are superimposed on each other and bonded to each other while the liquid crystal cell regions 2 of both of them are accurately positioned with the alignment-treated surfaces opposed to each other (bonding step S11).

Thereafter, the seal compound is cured (seal curing step S12).

The base material 1 for obtaining multiple liquid crystal cells shown in FIG. 1 is obtained through the seal curing step S12. In the base material 1 for obtaining multiple liquid crystal cells, a plurality of liquid crystal cell regions 2 to be made individual liquid crystal cells after manufacture are adjacently disposed in a row in each of the line direction and column direction. Specifically, in the base material 1 for obtaining multiple liquid crystal cells, the liquid crystal cell regions 2 are disposed adjacently to one another in a matrix form.

By arranging the liquid crystal cell regions 2 adjacently in a matrix form like this in the base material 1 for obtaining multiple liquid crystal cells, the glass substrate for an array substrate and the glass substrate for an opposite substrate can be used without wasting anything, and the number of process steps when cutting them in the first cutting step S13 and the second cutting step S17 which will be described later can be reduced.

Further, even when the liquid crystal cell regions 2 are arranged adjacently to one another in a matrix form in the base material 1 for obtaining multiple liquid crystal cells, the connecting wiring line 8 connecting the adjacent shield patterns 4a and 4b is formed in the border C of each of the liquid crystal cell regions as described in FIGS. 2, 3 and 4, and therefore, reduction in yield in manufacturing liquid crystal cells due to electrostatic discharge can be suppressed.

Thereafter, the glass substrate for an array substrate and the glass substrate for an opposite substrate which are bonded to each other are cut along the borders of the liquid crystal cell regions 2 (first cutting step S13).

Through the first cutting step S13, a plurality of rectangular base materials 3 for liquid crystal cells shown in FIG. 2 are obtained.

In FIG. 2, in the rectangular base material 3 for liquid crystal cells, a plurality of liquid crystal cell regions 2 are arranged adjacently in a line.

In the rectangular base material 3 for liquid crystal cells shown in FIG. 2, the shield patterns 4a and the shield pattern 4b are formed along the boarder between each of the liquid crystal cell regions 2 and another adjacent liquid crystal cell region 2. Out of the shield patterns 4a and 4b, only the shield pattern 4a is connected to the opposite electrode formed in the liquid crystal cell region 2 of the glass substrate for an opposite substrate through the conductive paste 5, that is, the common transfer material. Connection of the shield pattern 4a and the opposite electrode formed in the liquid crystal cell region 2 of the glass substrate for an opposite substrate is performed after the bonding step S11.

In the rectangular base material 3 for liquid crystal cells shown in FIG. 2, the shield patterns 4a and 4b which are opposed to each other across the boarder to which a pair of liquid crystal cell regions 2 adjacent to each other are adjacent are connected by the connecting wiring line 8. Accordingly, in the rectangular base material 3 for liquid crystal cells, reduction in yield in manufacturing the liquid crystal cells due to electrostatic discharge can be suppressed as in the base material 1 for obtaining multiple liquid crystal cells.

Next, the liquid crystal material is injected into a clearance formed by the glass substrate for an opposite substrate and the glass substrate for an array substrate in a plurality of liquid crystal cell regions from the liquid crystal injection holes 6 of the rectangular base material 3 for liquid crystal cells shown in FIG. 2 (liquid crystal injecting step S14).

Thereafter, the liquid crystal injection holes 6 of the rectangular base material 3 for liquid crystal cells are sealed by using the sealing compound 7 (sealing step S15).

Subsequently, polarizing plates are bonded to both sides of each of the liquid crystal cell regions 2 of the rectangular base material 3 for liquid crystal cells (polarizing plate bonding step S16).

Finally, the rectangular base material 3 for liquid crystal cells is cut at the borders of the respective liquid crystal cell regions 2. (second cutting step S17).

As above, the liquid crystal display panel body is fabricated.

In the base material 1 for obtaining multiple liquid crystal cells shown in FIG. 1 and the rectangular base material 3 for liquid crystal cells shown in FIG. 2, the shield pattern 4a and the shield pattern 4b are formed along the border C between each of the liquid crystal cell regions 2 and another adjacent liquid crystal cell region, and the shield pattern 4a and the shield pattern 4b are connected by the connecting wiring line 8. Accordingly, even if in each of the steps described in FIGS. 6(a) and 6(c), electrostatic discharge occurs as described above and ESD surge flows into the liquid crystal cell region 2, the ESD surge can be restrained from flowing into the inside of the liquid crystal cell regions 2 from the shield pattern 4a and the shield pattern 4b. Accordingly, ESD surge is prevented from flowing into the scanning lines and TFTs formed inside the liquid crystal cell regions 2, and the TFTs and the like formed inside the liquid crystal cell regions 2 are prevented from being damaged by the ESD surge.

The substrate for an array substrate of the present invention is not limited to the glass substrate for an array substrate which is a substrate of glass in the present embodiment. The substrate for an array substrate of the present invention may be a plastic substrate, a substrate formed of quartz and the like, in short, may be any substrate if only pixel electrodes, TFTs, shield patterns, connecting wiring lines and the like are formable on the substrate.

Further, the substrate for an opposite substrate of the present invention is not limited to the glass substrate for an opposite substrate which is the substrate of glass in the present embodiment. The substrate for an opposite substrate of the present invention may be a plastic substrate, a substrate formed of quartz and the like, in short, may be any substrate if only opposite electrodes, and a color filter are formable on the substrate.

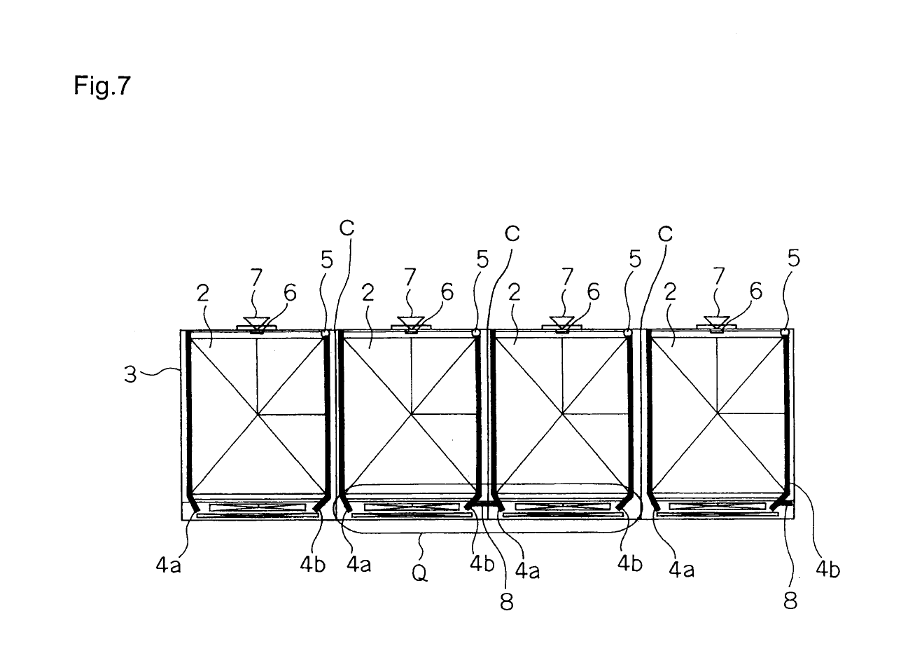

Further, in the present embodiment, it is described that the connecting wiring line 8 is used in all cases to have a connection to between the shield patterns 4a and 4b which are opposed to each other across the border of the liquid crystal cell regions 2 as explained with FIG. 2 and the like, but the present invention is not limited to this. For example, as in the configuration example shown in FIG. 7, it may be possible that only the shield pattern 4a and the shield pattern 4b which are adjacent across the border of the second liquid crystal cell region 2 from the left and the third liquid crystal cell region from the left may be connected by the connecting wiring line 8, and the other shield patterns 4a and shield patterns 4b do not be connected by the connecting wiring lines.

In short, the connecting wiring line 8 only has to connect the shield patterns 4a and 4b which are adjacent across the border to which at least a pair of liquid crystal cell regions 2 adjacent to each other are adjacent.

The shield pattern 4a and the shield pattern 4b differ in shape from each other in the portions to which the connecting wiring line 8 is connected as shown in FIG. 4. Specifically, the shield pattern 4b is in a linear shape in a portion U′ to which the connecting wiring line 8 is connected, but the width at the tail end is small, whereas the shield pattern 4a is crooked in a portion V′ to which the connecting wiring line 8 is connected, and the width is larger than that of the shield pattern 4b.

Due to the design of the liquid crystal cell, the width of the portion U′ of the shield pattern 4b sometimes has to be smaller than the portion U′ shown in FIG. 4. Specifically, when a shield pattern 4b′ is too close to the border of the liquid crystal cell regions 2 which are adjacent to each other, the width of the portion U′ needs to be smaller than that shown in FIG. 4 in order to enhance cutting accuracy. In such a case, the width of the portion U′ becomes significantly small as compared with the width of the portion V′. Even in such a case, by forming the connecting wiring line 8, the equivalent effect to the present embodiment can be obtained.

Further, when the shield pattern 4a and the shield pattern 4b differ in shape such as width from each other in the portions to which the connecting wiring line 8 is connected, ESD surge can be more reliably prevented from flowing to the inside of the liquid crystal cell regions 2 by making the resistance of the finer shield pattern equal to the resistance of the thicker shield pattern.

Further, equalizing the resistances in the portions to which the connecting wiring line 8 is connected in the shield pattern 4a and the shield pattern 4b can be realized as follows.

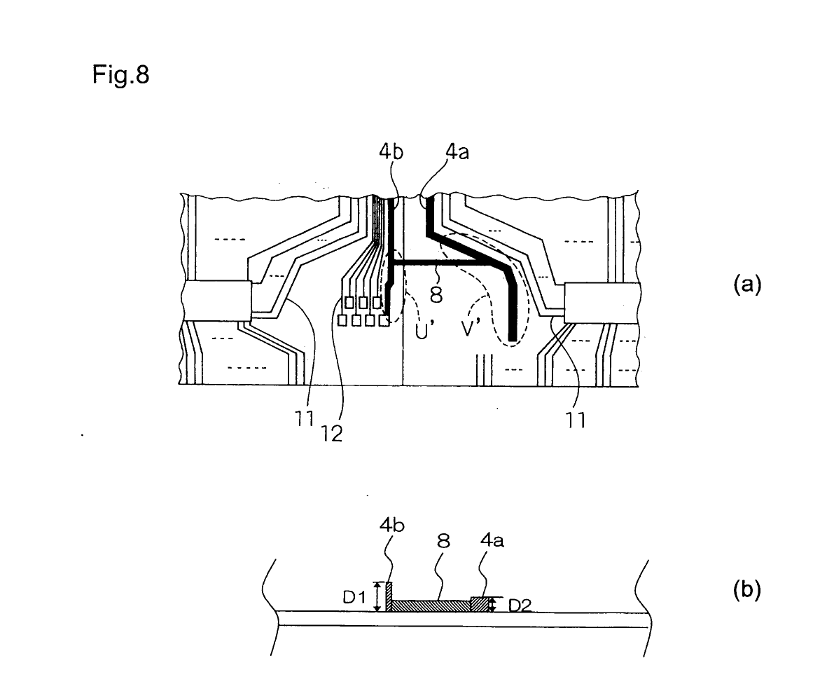

Specifically, as shown in FIG. 8(b) which is a schematic sectional view of FIG. 8(a) which is a plane view of the same shape as FIG. 4, the equalization can be realized by making a thickness D1 of the portion U′, to which the connecting wiring line 8 is connected, of the finer shield pattern 4b larger than a thickness D2 of the portion V′, to which the connecting wiring line 8 is connected, of the thicker shield pattern 4a. Alternatively, in FIG. 4, the equalization can also be realized by making the electric conductivity of the portion U′, to which the connecting wiring line 8 is connected, of the finer shield pattern 4b larger than the electric conductivity of the portion V′, to which the connecting wiring line 8 is connected, of the thicker shield pattern 4a.

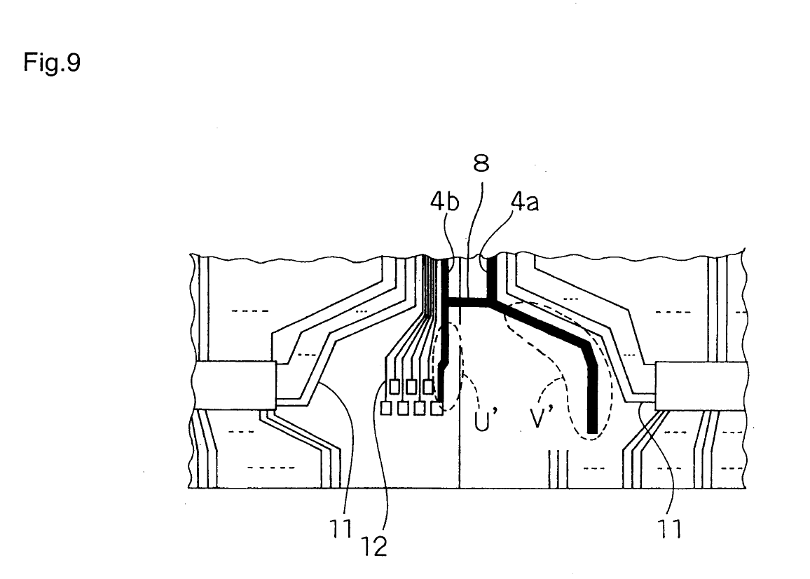

Further, in the above description, the connecting wiring line 8 is provided at the position where the shield pattern 4a and the shield pattern 4b are away from each other, but as shown in FIG. 9, the connecting wiring line 8 may be provided at the portion where the shield pattern 4a and the shield pattern 4b are parallel with each other. In short, the connecting wiring line of the present invention is not limited by its disposition as long as it can electrically connect the shield patterns. Further, the shape of the connecting wiring line 8 is a band shape with a uniform width, but may be in a curved shape, or the width may be partially varied. In short, the connecting wiring line of the present invention is not limited by its shape.

### INDUSTRIAL APPLICABILITY

The rectangular base material for liquid crystal cells, the base material for obtaining multiple liquid crystal cells, the substrate for an array substrate and the manufacturing method of a liquid crystal cell according to the present invention have the effect of being capable of suppressing reduction in yield due to electrostatic discharge, and are useful in a rectangular base material for liquid crystal cells, a base material for obtaining multiple liquid crystal cells, a substrate for an array substrate, a manufacturing method of a liquid crystal cell and the like in which measures against electrostatic discharge (ESD) is performed in a manufacturing process of liquid crystal cells and the like.

1: A rectangular base material for liquid crystal cells having a substrate for an array substrate and a substrate for an opposite substrate bonded to said substrate for an array substrate, and having a plurality of liquid crystal cell regions arranged adjacently to one another in a line on said substrate for an array substrate and said substrate for an opposite substrate, comprising:
a pixel electrode pattern formed in a matrix form in said liquid crystal cell regions on said substrate for an array substrate;
a predetermined control wiring pattern formed on said liquid crystal cell region on said substrate for an array substrate and for being connected to said pixel electrode pattern;
a shield pattern which is formed in said liquid crystal cell region on said substrate for an array substrate, is disposed outside said predetermined control wiring pattern along a border with another adjacent liquid crystal cell region, and is for shielding said liquid crystal cell region; and
a connecting wiring line electrically connecting said shield patterns adjacent across the border to which at least a pair of said liquid crystal cell regions adjacent to each other are adjacent.

2: The rectangular base material for liquid crystal cells according to claim 1,
wherein an opposite electrode is formed in each of said liquid crystal cell regions on said substrate for an opposite substrate, and
only one of said adjacent shield patterns is connected to said opposite electrode via a conductive member.

3: The rectangular base material for liquid crystal cells according to claim 1,
wherein a line width of one of said adjacent shield patterns is smaller than a line width of the other one at portions to which said connecting wiring line is connected.

4: The rectangular base material for liquid crystal cells according to claim 1,
wherein widths of said adjacent shield patterns differ from each other at portions to which said connecting wiring line is connected, and
resistance of said portion of said shield pattern of a small width and resistance of said portion of said shield pattern of a large width are equal.

5: The rectangular base material for liquid crystal cells according to claim 4,
wherein a thickness of said portion of said shield pattern of the small width is larger than a thickness of said portion of said shield pattern of the large width.

6: The rectangular base material for liquid crystal cells according to claim 4,
wherein electrical conductivity of said portion of said shield pattern of the small width is higher than electrical conductivity of said portion of said shield pattern of the large width.

7: The base material for obtaining multiple liquid crystal cells from which a plurality of the rectangular base materials for liquid crystal cells according to claim 1 can be obtained by cutting.

8: A substrate for an array substrate having a plurality of liquid crystal cell regions arranged adjacently to one another in a line, comprising:
a pixel electrode pattern formed in a matrix form in said liquid crystal cell region;
a predetermined control wiring pattern formed in said liquid crystal cell region and for being connected to said pixel electrode pattern;
a shield pattern which is formed in said liquid crystal cell region, is disposed outside said predetermined control wiring pattern along a border with another adjacent liquid crystal cell region, and is for shielding said liquid crystal cell region; and
a connecting wiring line electrically connecting said shield patterns adjacent across a border to which at least a pair of said liquid crystal cell regions adjacent to each other are adjacent.

9: A manufacturing method of a liquid crystal cell, comprising:
a pixel electrode pattern forming step for forming a pixel electrode pattern disposed in a matrix form in a plurality of liquid crystal cell regions arranged adjacently to one another in a line on a substrate for an array substrate;
a control wiring pattern forming step of forming a predetermined control wiring pattern for being connected to said pixel electrode pattern in said liquid crystal cell regions on said substrate for an array substrate;
a shield pattern forming step of forming a shield pattern, which is disposed outside said predetermined control wiring pattern along a border of said liquid crystal cell region on said substrate for an array substrate with another adjacent liquid crystal cell region and is for shielding said liquid crystal cell region;
a connecting wiring line forming step of electrically connecting said shield patterns adjacent across the border to which at least a pair of said liquid crystal cell regions adjacent to each other are adjacent;
a bonding step of bonding a substrate for an opposite substrate having a plurality of liquid crystal cell regions adjacent to one another in a line and said substrate for an array substrate to each other by a sealing compound so that said plurality of liquid crystal cell regions correspond to one another to obtain a base material for obtaining multiple liquid crystal cells;
a first cutting step of cutting said base material for obtaining multiple liquid crystal cells in a horizontal direction to obtain a rectangular base material for liquid crystal cells;
an injecting step of injecting a liquid crystal material in clearances formed by said substrate for an array substrate and said substrate for an opposite substrate in said plurality of liquid crystal cell regions of said rectangular base material for liquid crystal cells; and
a second cutting step of cutting said rectangular base material for liquid crystal cells at the borders of said liquid crystal cell regions.
